(19) United States
(12) Patent Application Publication
(10) Pub. No.: US 2026/0198147 A1
(43) Pub. Date: Jul. 9, 2026

(54) LIGHT-EMITTING DEVICE, DISPLAY DEVICE EMPLOYING THE SAME, METHOD OF MANUFACTURING THE SAME, ELECTRONIC APPARATUS HAVING THE DISPLAY DEVICE

(71) Applicant: SAMSUNG ELECTRONICS CO., LTD., Suwon-si (KR)

(72) Inventors: Sungmo AHN, Suwon-si (KR); Sangyun LEE, Suwon-si (KR); Sookyoung ROH, Suwon-si (KR); Kyungwook HWANG, Suwon-si (KR)

(73) Assignee: SAMSUNG ELECTRONICS CO., LTD., Suwon-si (KR)

(21) Appl. No.: 19/361,531

(22) Filed: Oct. 17, 2025

(30) Foreign Application Priority Data
Jan. 7, 2025 (KR) 10-2025-0002384

(51) Int. Cl. H10H 20/855; H10H 20/01; H10H 20/813; H10H 20/825; H10H 20/856; H10H 29/14

(52) U.S. Cl. CPC H10H 20/855; H10H 20/0363; H10H 20/8131; H10H 20/825; H10H 20/856; H10H 29/142

(57) ABSTRACT

A light-emitting device may include a vertically stacked structure including a plurality of epitaxial structures stacked in a vertical direction and provided to generate different wavelength lights, respectively, a light concentrator provided in a protruding shape with respect to the vertically stacked structure, a micro-lens apart from the light concentrator, and a separation layer between the light concentrator and the micro-lens. Each of the plurality of epitaxial structures includes a first conductive semiconductor layer, an active layer, and a second conductive semiconductor layer, and the light concentrator is configured to reduce a beam directivity angle of emitting light condensed by the micro-lens.

### CROSS-REFERENCE TO RELATED APPLICATION

This application is based on and claims priority under 35 U.S.C. § 119 to Korean Patent Application No. 10-2025-0002384, filed on Jan. 7, 2025, in the Korean Intellectual Property Office, the disclosure of which is incorporated by reference herein in its entirety.

### BACKGROUND

### 1. Field

The disclosure relates to a light-emitting device, a display device, and a method of manufacturing the light-emitting device, and an electronic apparatus including the same.

### 2. Description of the Related Art

Light-emitting diodes (LEDs) have advantages, such as long lifetime, low power consumption, fast response speed, and environmental friendliness, and thus, industrial demand is increasing due to these advantages.

Recently, the technology for manufacturing high-resolution display devices using micro-LEDs has been in the spotlight. LED displays that directly use these micro-LEDs as pixels are being developed and commercialized. LED display pixels may be designed in various ways, and recently, various technologies in which micro-LEDs (R-LEDs) that emit red light R, micro-LEDs (G-LEDs) that emit green light G, and micro-LEDs (B-LEDs) that emit blue light B are vertically stacked have been introduced. However, so far, satisfactory results have not yet been obtained in terms of light extraction efficiency and beam directivity angle from vertically stacked micro-LEDs.

### SUMMARY

One or more embodiments of the present disclosure provide a light-emitting device having a vertically stacked structure of an epi structure and a method of manufacturing the same.

Further, one or more embodiments of the present disclosure provide a display device having a vertically stacked structure of an epi structure and a method of manufacturing the same.

Further, one or more embodiments of the present disclosure provide an electronic apparatus including a display device having a vertically stacked structure of an epi structure.

According to an aspect of the disclosure, a light-emitting device may include: a vertically stacked structure including a plurality of epitaxial structures stacked in a vertical direction and provided to generate different wavelength lights, respectively; a light concentrator provided in a protruding shape with respect to the vertically stacked structure; a micro-lens apart from the light concentrator; and a separation layer between the light concentrator and the micro-lens, wherein each of the plurality of epitaxial structures may include a first conductive semiconductor layer, an active layer, and a second conductive semiconductor layer, and the light concentrator is configured to reduce a beam directivity angle of emitting light condensed by the micro-lens.

The light-emitting device may further include a reflective layer that surround at least one of side and bottom surfaces of the vertically stacked structure.

The light concentrator may protrude from a center of an upper surface of the vertically stacked structure.

The light concentrator may have a shape of any one of a columnar shape, a cone shape, a pyramid shape, a truncated cone shape, and a truncated pyramid shape to protrude from the vertically stacked structure, and a cross-sectional shape of the light concentrator may be any one of a circle, an ellipse, a square, and a polygon.

A width of the light concentrator may be 50% or less of a width of an upper surface of the vertically stacked structure, or a height of the light concentrator is less than or equal to 1 μm.

A refractive index of the light concentrator may be greater than a refractive index of the separation layer.

An epitaxial structure adjacent to the light concentrator of the vertically stacked structure may be based on a Group III-V compound semiconductor, and the light concentrator may include either titanium dioxide (TiO₂) or silicon nitride (SiN).

The light concentrator is formed by patterning a portion of a thickness of an epitaxial structure adjacent to the light concentrator of the vertically stacked structure, and the light-emitting device may further include an anti-reflection layer between the light concentrator and the separation layer.

The light-emitting device may further include a plurality of protrusion patterns formed by patterning an epitaxial structure adjacent to the light concentrator of the vertically stacked structure around the light concentrator. The plurality of protrusion patterns may further include a plurality of annular grating structures around the light concentrator, or the plurality of protrusion patterns are two-dimensionally arranged around the light concentrator.

The light concentrator may further include a plurality of light concentrators that protrude from the vertically stacked structure. The plurality of light concentrators may have the same or different heights or the same or different cross sectional sizes.

According to an aspect of the disclosure, a display device may include: a backplane substrate including at least one driving element and light-emitting devices provided in a two-dimensional array on the backplane substrate. At least one of the light-emitting devices may include: a vertically stacked structure including a plurality of epitaxial structures stacked in a vertical direction with respect to the backplane substrate and configured to generate different wavelength lights from each other; a light concentrator provided in a protruding shape with respect to the vertically stacked structure; a micro-lens apart from the light concentrator; and a separation layer between the light concentrator and the micro-lens. Each of the plurality of epitaxial structures may include a first conductive semiconductor layer, an active layer, and a second conductive semiconductor layer, and the light concentrator may be configured to reduce a beam directivity angle of emitting light condensed by the micro-lens.

The display device may further include a reflective layer that surrounds at least one of side and bottom surfaces of the vertically stacked structure.

The light concentrator may protrude from a center of an upper surface of the vertically stacked structure.

The light concentrator may have a shape of any one of a columnar shape, a cone shape, a pyramid shape, a truncated cone shape, and a truncated pyramid shape to protrude from the vertically stacked structure, and a cross-sectional shape of the light concentrator may be any one of a circle, an ellipse, a square, and a polygon.

A width of the light concentrator is 50% or less of a width of an upper surface of the vertically stacked structure and a height of the light concentrator may be equal to or less than 1 μm.

The light concentrator may have a refractive index greater than that of the separation layer.

An epitaxial structure adjacent to the light concentrator of the vertically stacked structure may be based on a Group III-V compound semiconductor, and the light concentrator includes either TiO₂ or SiN.

The light concentrator may be formed by patterning a portion of a thickness of an epitaxial structure adjacent to the light concentrator of the vertically stacked structure and may further include an anti-reflection layer between the light concentrator and the separation layer.

The light concentrator may include a plurality of light concentrators that protrude on the vertically stacked structure, and the plurality of light concentrators may have the same or different heights or the same or different cross-sectional sizes.

According to an aspect of the disclosure, a method of manufacturing a display device, the method includes forming a vertically stacked structure including a plurality of epitaxial structures that are vertically stacked on a substrate and provided to generate different wavelength light from each other, forming a backplane substrate, combining the backplane substrate and the vertically stacked structure so that the vertically stacked structure faces the backplane substrate, removing the substrate, forming a light concentrator in a protruding shape with respect to the vertically stacked structure, forming a separation layer on the light concentrator, and forming a micro-lens on the separation layer, wherein the forming of each of the plurality of epi structures includes forming a first conductive semiconductor layer, forming an active layer, and forming a second conductive semiconductor layer, and the light concentrator may be provided to reduce a beam directivity angle of emitting light condensed by the micro-lens.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a light-emitting device according to one or more embodiments;

FIG. 2 shows an example of a light proceeding path in the light-emitting device of FIG. 1;

FIG. 3 and FIG. 4 show examples in which light-emitting devices according to embodiments include a plurality of light concentrators provided to protrude on a vertically stacked structure;

FIG. 5 and FIG. 6 show examples in which light-emitting devices according to embodiments include a light concentrator formed by patterning a portion of a thickness of an epi structure adjacent to a vertically stacked structure;

FIG. 7A shows a schematic cross-sectional image of a light-emitting device according to one or more embodiments used in the simulation, FIG. 7B shows a cross-sectional view of an FDTD simulation field profile, and FIG. 7C shows a plan view of an FDTD simulation field profile.

FIG. 8 and FIG. 9 are graphs showing an extraction efficiency of red light, green light, and blue light at different angles of a vertically stacked light-emitting device according to one or more embodiments depending on parameters of a light concentrator;

FIGS. 10 to 14 are schematic cross-sectional views of display devices according to embodiments;

FIG. 15 is a diagram for explaining a method of manufacturing a light-emitting device and a display device according to one or more embodiments;

FIG. 16 is a block diagram of an electronic apparatus including a display device according to one or more embodiments;

FIG. 17 is an example in which an electronic apparatus according to one or more embodiments is applied to a mobile device;

FIG. 18 is an example in which a display device according to one or more embodiments is applied to a vehicle;

FIG. 19 is an example in which a display device according to one or more embodiments is applied to augmented reality glasses or virtual reality glasses;

FIG. 20 is an example in which a display device according to one or more embodiments is applied to a large signage; and

FIG. 21 is an example in which a display device according to one or more embodiments is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings. In the drawings below, like reference numerals refer to like components, and the size of each component in the drawings may be exaggerated for clarity and convenience of explanation. The embodiments of the disclosure are capable of various modifications and may be embodied in many different forms.

When an element or layer is referred to as being “on” or “above” another element or layer, the element or layer may include not only the element being “immediately on/under/left/right in a contact manner” but also being “on/under/left/right in a non-contact manner”. The singular forms include the plural forms unless the context clearly indicates otherwise. When a part “comprises” or “includes” an element in the specification, unless otherwise defined, other elements are not excluded from the part and the part may further include other elements

The term “above” and similar directional terms may be applied to both singular and plural. Operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “. . . modules” denote units or modules that process at least one function or operation, and may be realized by hardware, software, or a combination of hardware and software.

The connections of lines and connection members between constituent elements depicted in the drawings are examples of functional connection and/or physical or circuitry connections, and thus, in practical devices, may be expressed as replaceable or additional functional connections, physical connections, or circuitry connections.

All examples or example terms are simply used to explain in detail the technical scope of the disclosure, and thus, the scope of the disclosure is not limited by the examples or the example terms as long as it is not defined by the claims.

In order to implement color, for example, RGB color, a micro-LED based on a Group III-V compound semiconductor such as gallium nitride (GaN), may be required, and it may be necessary to extract light outside the micro-LED due to total reflection at an interface between a GaN material and a medium region having a lower refractive index, for example, air.

For example, a light extraction efficiency may be increased by making irregularities on a surface of a GaN layer in various ways. In addition, in order to implement a high-resolution augmented reality (AR) display, an optical structure that narrows a beam directivity angle extracted outside the micro-LED may be applied. For example, the beam directivity angle may be narrowed by integrating a micro-lens structure on the micro-LED. However, in order to implement a high-resolution micro-LED display, a gap between each micro-LED becomes narrow, and thus, a size of the micro-lens to be integrated to narrow the beam directivity angle is limited. When the size of the micro-lens is difficult to be greater than a size of the micro-LED, it may be difficult to adjust the beam directivity angle, and as a result, it may be difficult to secure amount of light required for implementing an AR display. In addition, in the case of a vertical RGB monolithic LED, because each of RGB light-emitting layers (active layers) is formed in a vertical direction about one light-emitting device, an additional optical structure is required to collimate each RGB light from the RGB light-emitting layers at different heights with one micro-lens. The light-emitting device according to one or more embodiments and the display device including the same are provided with a light concentrator, which is a structure capable of concentrating light on a vertically stacked structure, and thus, is provided to increase the light extraction efficiency and reduce a beam directivity angle.

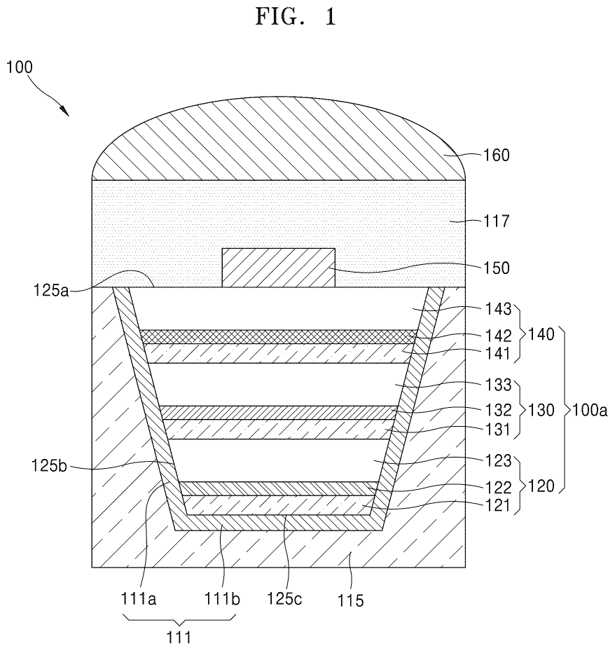

FIG. 1 is a schematic cross-sectional view of a light-emitting device 100 according to one or more embodiments.

Referring to FIG. 1, the light-emitting device 100 may include a vertically stacked structure 100a corresponding to a light-emitting element, a light concentrator 150 provided in a protruding shape with respect to the vertically stacked structure 100a, a micro-lens 160 apart from the light concentrator 150, and a separation layer 117 provided between the light concentrator 150 and the micro-lens 160. For example, the light concentrator 150 may protrude from or extend outward from the vertically stacked structure 100a.

The vertically stacked structure 100a may include a plurality of epi structures 120, 130, and 140 that are sequentially stacked in a vertical direction. An epi structure may refer to a semiconductor epitaxial structure. For example, an epi structure may be formed with an arrangement of semiconductor materials grown on a crystalline layer using epitaxy. The plurality of epi structures 120, 130, and 140 are provided to generate light of different wavelengths, for example, red, green, and blue lights. The plurality of epi structures 120, 130, and 140 may include, for example, a first epi structure 120, a second epi structure 130, and a third epi structure 140, but is not limited thereto. Hereinafter, one or more embodiments in which the plurality of epi structures 120, 130, and 140 include the first epi structure 120, the second epi structure 130, and the third epi structure 140 is described as an example.

The first epi structure 120, may include, for example, a first conductive semiconductor layer 121, an active layer 122, and a second conductive semiconductor layer 123, the second epi structure 130 may include a first conductive semiconductor layer 131, an active layer 132, and a second conductive semiconductor layer 133, and the third epi structure 140 may include, a first conductive semiconductor layer 141, an active layer 142, and a second conductive semiconductor layer 143. The first epi structure 120 may be configured to generate first wavelength light, the second epi structure 130 may be configured to generate second wavelength light, and the third epi structure 140 may be configured to generate third wavelength light. The first wavelength light, the second wavelength light, and the third wavelength light may have different wavelengths. The first epi structure 120, the second epi structure 130, and the third epi structure 140 may include, for example, a material based on a Group III-V compound semiconductor.

For example, the first conductive semiconductor layers 121, 131, and 141 may be p-type semiconductor layers based on a Group III-V compound semiconductor. Alternatively, the first conductive semiconductor layers 121, 131, and 141 may be n-type semiconductor layers based on a Group III-V compound semiconductor. The first conductive semiconductor layers 121, 131, and 141 may include a p-type semiconductor material of a Group III-V, for example, p-type gallium nitride (p-GaN), p-type indium gallium nitride (p-InGaN), p-type aluminum indium gallium nitride (p-AlInGaN), or p-type aluminum gallium indium phosphide (p-AlGaInP). The first conductive semiconductor layers 121, 131, and 141 may have a single-layer or multi-layer structure.

The active layers 122, 132, and 142 may be provided on the corresponding first conductive semiconductor layers 121, 131, and 141, respectively. The active layers 122, 132, and 142 may generate light when electrons and holes combine. The active layer 122 of the first epi structure 120 may generate the first wavelength light, for example, red wavelength light. The active layer 132 of the second epi structure 130 may generate the second wavelength light, for example, green wavelength light. The active layer 142 of the third epi structure 140 may generate the third wavelength light, for example, blue wavelength light. However, the active layers 122, 132, and 142 are not limited thereto. The active layers 122, 132, and 142 may have a multi-quantum well (MQW) structure or a single-quantum well (SQW) structure. The active layers 122, 132, and 142 may include a Group III-V compound semiconductor material, for example, GaN, InGaN, AlInGaN, or AlGaInP. The active layers 122, 132, and 142 may include, for example, an InGaN/GaN quantum well structure. The greater the content of indium (In) included in the active layers 122, 132, and 142, the longer a wavelength of light emitted from the active layers 122, 132, and 142.

The second conductive semiconductor layers 123, 133, and 143 may be formed on the corresponding active layers 122, 132, and 142, respectively. The second conductive semiconductor layers 123, 133, and 143 may be, for example, n-type semiconductor layers based on a Group III-V compound semiconductor. Alternatively, the second conductive semiconductor layers 123, 133, and 143 may be p-type semiconductor layers based on a Group III-V compound semiconductor. The second conductive semiconductor layers 123, 133, and 143 may include an n-type semiconductor material of a Group III-V, for example, n-GaN, n-InGaN, n-AlInGaN, or n-AlGaInP. The second conductive semiconductor layers 123, 133, and 143 may have a single layer or multilayer structure.

The light-emitting device 100 may further include a reflective layer 115 that surrounds at least one of a side surface 125b and a bottom surface 125c of the vertically stacked structure 100a. The reflective layer 115 may be formed of, for example, a metal material. In addition, the light-emitting device 100 may further include a passivation layer 111 that protects the vertically stacked structure 100a. The passivation layer 111 may be disposed between the vertically stacked structure 100a and the reflective layer 115. FIG. 1 shows an example in which the reflective layer 115 and the passivation layer 111 may surround the side surface 125b and the bottom surface 125c of the vertically stacked structure 100a. The passivation layer 111 may include a side portion 111a positioned between the side surface 125b of the vertically stacked structure 100a and the reflective layer 115, and a bottom portion 111b positioned between the bottom surface 125c of the vertically stacked structure 100a and the reflective layer 115.

A significant amount of light generated from the active layers 122, 132, and 142 of each of the first epi structure 120, the second epi structure 130, and the third epi structure 140 of the vertically stacked structure 100a is totally reflected from an upper surface 125a of the vertically stacked structure 100a and proceeds inside the vertically stacked structure 100a. In addition, as illustrated in FIG. 1, when the reflective layer 115 is provided to surround the side surface 125b and the bottom surface 125c of the vertically stacked structure 100a, light passing through each boundary of the side surface 125b and the bottom surface 125c of the vertically stacked structure 100a is reflected by the reflective layer 115 and proceeds inside the vertically stacked structure 100a again.

Here, light incident at an angle less than a total reflection angle at boundary surfaces (i.e., the side surface 125b, the bottom surface 125c, and the upper surface 125a) of the vertically stacked structure 100a may be partially transmitted and partially reflected. The reflected light may proceed within the vertically stacked structure 100a. In addition, light that transmits through a portion of the upper surface 125a other than the light concentrator 150 may exist. However, the transmitted light may be weaker than the light that is first concentrated and then extracted through the light concentrator 150. In addition, according to an embodiment, such transmitted light may be considered ineffective because it is difficult to be collimated into a narrow beam directivity angle by the micro-lens 160. The beam directivity angle may be also referred to as a beam divergence angle that is a measure of how much a beam of light spreads out as it propagate from a light source.

In this way, light emitted from each of the first epi structure 120, the second epi structure 130, and the third epi structure 140 of the vertically stacked structure 100a proceeds through the inside of the vertically stacked structure 100a by total reflection and reflection in the reflective layer 115, and then is refracted and exits from the light concentrator 150 provided on the upper surface 125a of the vertically stacked structure 100a at an angle less than the total reflection angle.

The light concentrator 150 may increase a light extraction efficiency from the vertically stacked structure 100a and reduce a beam directivity angle of emitting light condensed by the micro-lens 160. Because the light concentrator 150 may reduce the beam directivity angle of the emitting light, for example, when implementing a high-resolution micro-LED display by applying the light-emitting devices 100 according to one or more embodiments as micro-LEDs, even when a gap between each micro-LEDs is narrow, thereby being limited a size of the micro-lens 160, it is possible to adjust a directivity angle and secure amount of light required for implementing an AR display.

The separation layer 117 may be provided between the light concentrator 150 and the micro-lens 160. The separation layer 117 may cover the light concentrator 150 to secure a separation distance between the light concentrator 150 and the micro-lens 160. The micro-lens 160 may be disposed on the separation layer 117. The micro-lens 160 may be provided, for example, to collimate light diverging from a focus into parallel light.

The separation layer 117 may secure a separation distance that positions the light concentrator 150 approximately at a focus position of the micro-lens 160. The separation layer 117 may include air or a dielectric material. For example, the separation layer 117 may be a dielectric material layer. The separation layer 117 may be formed by depositing a dielectric material on the vertically stacked structure 100a on which the light concentrator 150 is formed. The separation layer 117 may include the same material as the micro-lens 160 or may include a material different from the micro-lens 160. Here, when the separation layer 117 include the same material as the micro-lens 160, the separation layer 117 may or may not be distinguished from the micro-lens 160 by an interface. As another example, the separation layer 117 may include an air layer. For example, the separation layer 117 may be composed of a plurality of posts for securing a separation distance between the light concentrator 150 and the micro-lens 160, and an air layer for filling a free space between the light concentrator 150 and the micro-lens 160.

The light concentrator 150 may include a material having a refractive index that is less or greater than that of an adjacent layer of an adjacent epi structure of the vertically stacked structure 100a, for example, the second conductive semiconductor layer 143 of the third epi structure 140, but not significantly different from that of the adjacent layer, for example, a similar refractive index, but greater than that of other adjacent layer in a light emission direction, for example, the separation layer 117. Alternatively, the light concentrator 150 may include the same material as an uppermost layer of the vertically stacked structure 100a, for example, the second conductive semiconductor layer 143 of the third epi structure 140. When a refractive index of the second conductive semiconductor layer 143 of the third epi structure 140 is n1, a refractive index of the light concentrator 150 is n2, and a refractive index of the separation layer 117 is n3, the light concentrator 150 may satisfy a relationship of n1>n3 and n2>n3 or a relationship of n1=n2>n3. For example, when the refractive index n1 of the second conductive semiconductor layer 143 is different from the refractive index n2 of the light concentrator 150, that is, when n1>n2 or n1<n2, a material of the light concentrator 150 may be selected so that a difference between n1 and n2 is not large.

For example, when the second conductive semiconductor layer 143 of the third epi structure 140, which is an epi structure adjacent to the light concentrator 150 of the vertically stacked structure 100a, is based on a Group III-V compound semiconductor, such as GaN, the light concentrator 150 may include either TiO₂ or SiN. Here, a refractive index of the GaN epi layer is ~2.4, TiO₂ may have a refractive index of ~2.7, and SiN may have a refractive index of ~2. For example, the second conductive semiconductor layer 143 of the third epi structure 140 may be a GaN epi layer, and the light concentrator 150 may include TiO₂. In this case, n1<n2, but because n1~2.4 and n2~2.7, a difference between n1 and n2 is not large, and thus, it may be stated that the light concentrator 150 has a refractive index similar to that of the second conductive semiconductor layer 143 of the third epi structure 140. In addition, the second conductive semiconductor layer 143 of the third epi structure 140 may be a GaN epi layer, and the light concentrator 150 may include SiN. In this case, n1>n2, but because n1~2.4 and n2~2, a difference between n1 and n2 is not large, and thus, it may be stated that the light concentrator 150 has a refractive index similar to that of the second conductive semiconductor layer 143 of the third epi structure 140.

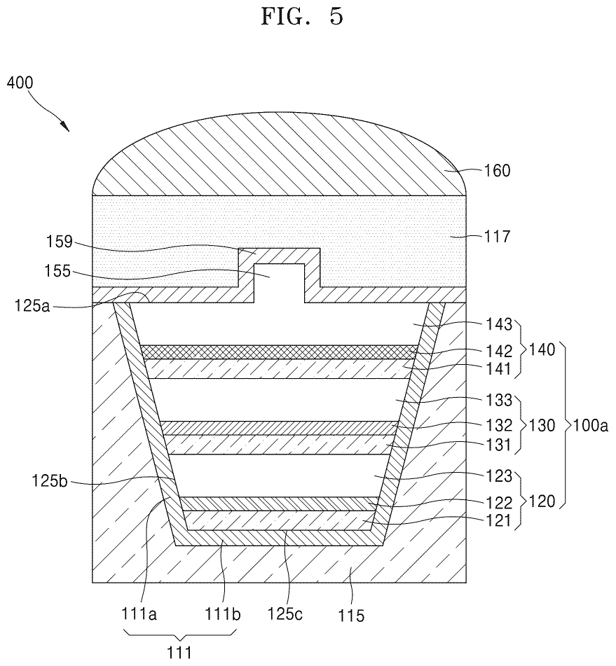

As another example, the light concentrator 150 may include the same material as an uppermost layer of the vertically stacked structure 100a, for example, the second conductive semiconductor layer 143 of the third epi structure 140. For example, the light concentrator 150 may include a Group III-V compound semiconductor, for example, a GaN material or a material based on GaN. For example, the second conductive semiconductor layer 143 of the third epi structure 140 may be a GaN epi layer, and the light concentrator 150 may include GaN, and in this case n1=n2. The light concentrator 150 may be formed as a separate layer from the uppermost layer of the vertically stacked structure 100a. As another example, the light concentrator 150 may be formed by patterning a portion of a thickness of an adjacent epi structure (e.g., the third epi structure 140) of the vertically stacked structure 100a. For example, a GaN epi layer may be selectively etched or partially removed to form a thinner residual layer as the third epi structure 140, and on top of the third epi structure 140, a cylindrical rod extending upwards from the third epi structure 140 is formed as the light concentrator 150. In this way, when the light concentrator 150 includes the same material as the uppermost layer of the vertically stacked structure 100a, the light-emitting device 100 may further include an anti-reflection layer 159 (see FIG. 5) between the light concentrator 150 and the separation layer 117.

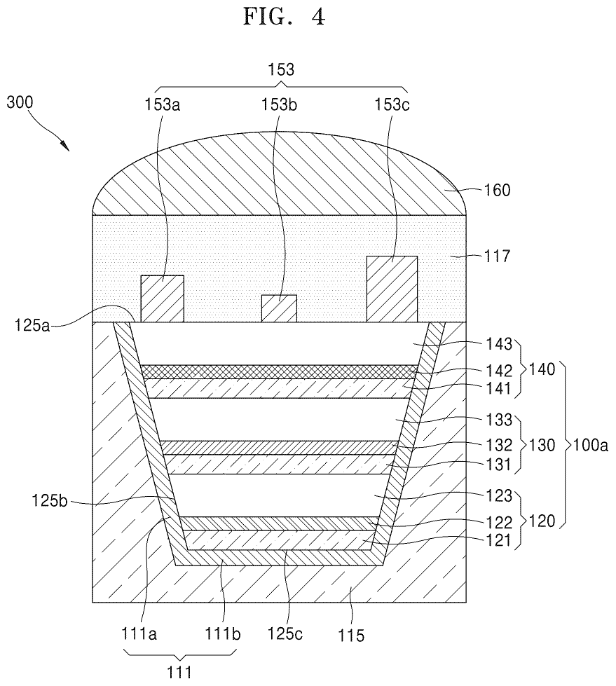

The light concentrator 150 may have a size of about 50% or less of a size of the vertically stacked structure 100a (e.g., a size of the upper surface 125a of the vertically stacked structure 100a on which the light concentrator 150 is formed or a width of the upper surface 125 a) and may be formed to a height of 1 μm or less. In addition, the light concentrator 150 may protrude from the upper surface 125a of the vertically stacked structure 100a, for example, in a center of the upper surface 125a. The light concentrator 150 may have any one of a columnar shape, a cone shape, a pyramid shape, a truncated cone shape, and a truncated pyramid shape, and the cross-sectional shape of the light concentrator 150 may have various shapes. For example, the cross-sectional shape of the light concentrator 150 may be any one of a circle, an oval, a square, and a polygon. As an example, the light concentrator 150 may have a cylindrical shape with a diameter of about 50% or less of the width of the upper surface 125a of the vertically stacked structure 100a and a height of 1 μm or less. As another example, the light concentrator 150 may be provided in a form in which a plurality of light concentrators 151 or 153 are arranged, as in FIG. 3 and FIG. 4 described below.

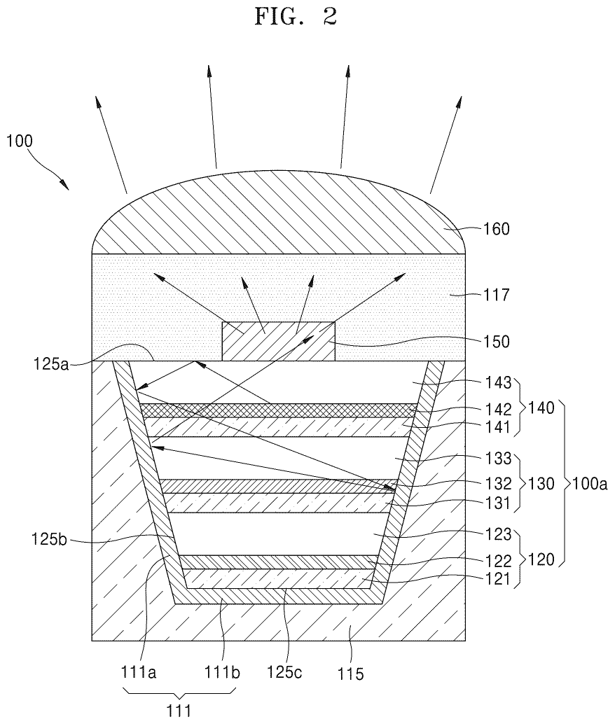

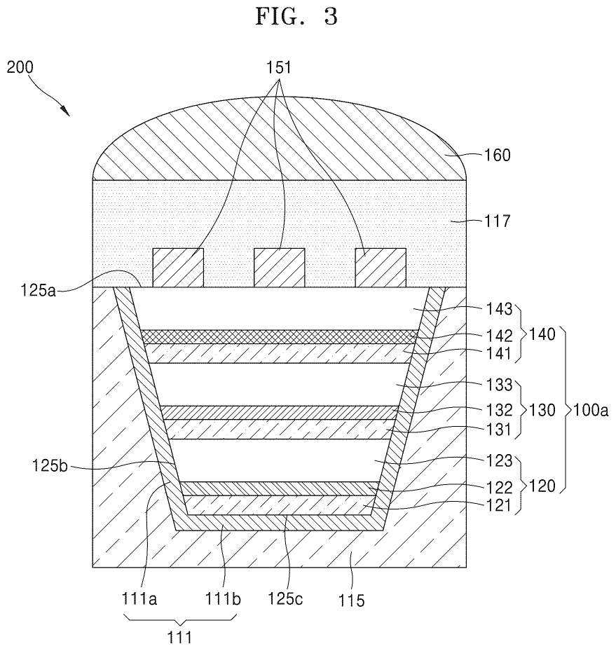

A significant amount of the first to third wavelength light generated in each of the active layers 122, 132, and 142 of the first to third epi structures 120, 130, and 140 is totally reflected from the upper surface 125a of the vertically stacked structure 100a, and is reflected from the reflective layer 115 surrounding the side surface 125b and the bottom surface 125c of the vertically stacked structure 100a, and then proceeds inside the vertically stacked structure 100a and is refracted at an angle less than the total reflection angle and exits toward the upper surface 125a. In this process, light may be mainly extracted through the light concentrator 150 protrudingly formed on the upper surface 125a of the vertically stacked structure 100a, as illustrated in FIG. 2. At this time, because the light concentrator 150 is approximately located at the focus position of the micro-lens 160, the light emitted from the light concentrator 150 may substantially correspond to light diverging from the focus position of the micro-lens 160.

In this way, the light generated in the vertically stacked structure 100a may be mainly extracted through the light concentrator 150, and because the light concentrator 150 is approximately located at the focus position of the micro-lens 160, the light extracted through the light concentrator 150 may substantially correspond to light diverging from the focus position of the micro-lens 160. Accordingly, the emitting light condensed by the micro-lens 160 may be light with a reduced beam directivity angle, that is, substantially parallel light.

FIG. 2 shows an example of a light proceeding path in the light-emitting device 100 of FIG. 1. A path of light illustrated as being reflected from the side surface 125b of the vertically stacked structure 100a in FIG. 2 is illustrated for convenience and may correspond to light reflected from the reflective layer 115.

As illustrated in FIG. 2, light that is totally reflected from the upper surface 125a of the vertically stacked structure 100a, reflected from the reflective layer 115, and proceeds the interior of the vertically stacked structure 100a is mainly extracted through the light concentrator 150 and may be collimated by the micro-lens 160. As a result, light output from the light-emitting device 100 may have a reduced beam directivity angle. For example, the light-emitting device 100 according to one or more embodiments may reduce the beam directivity angle of the emitting light condensed by the light concentrator 150 and then by the micro-lens 160, and may output light having a small beam directivity angle, for example, within a range of about −20° to about +20°.

The light-emitting device 100 according to one or more embodiments may be manufactured, for example, as follows. For example, the third epi structure 140, the second epi structure 130, and the first epi structure 120 are grown in order on a substrate, and then, the order is changed by flip after forming an electrode. In this way, the vertically stacked structure 100a stacked in the vertical direction in the order shown in FIGS. 1 and 2 may be formed. After removing the substrate, the light concentrator 150 may be formed on the third epi structure 140, and the separation layer 117 and the micro-lens 160 may be formed. For example, an uppermost layer of the third epi structure 140 may be an n-GaN layer, and the light concentrator 150 may be formed on a center of the n-GaN layer in a cylindrical shape with a radius of about 500 nm and a height of about 700 nm. At this time, the light concentrator 150 may be manufactured by a photo process and a dry etching process. The passivation layer 111 and the reflective layer 115 may surround the vertically stacked structure 100a in the order of the third epi structure 140, the second epi structure 130, and the first epi structure 120 before the flip.

The vertically stacked structure 100a of the light-emitting device 100 according to one or more embodiments may have the inclined side surface 125b facing the light concentrator 150, but is not limited thereto. When the vertically stacked structure 100a has an inclined side surface 125b facing the light concentrator 150, light proceeding through the interior of the vertically stacked structure 100a by total reflection and reflection in the reflective layer 115 may be more concentrated into the light concentrator 150. Therefore, light extraction efficiency through the light concentrator 150 may be increased, and amount of light emitted at a reduced beam directivity angle by being condensed by the micro-lens 160 may be increased.

When the light-emitting device 100 including the light concentrator 150 capable of improving light extraction efficiency and narrowing the beam directivity angle is applied, even when the gap between each micro-LED is narrowed to implement a high-resolution micro-LED display, the amount of light required for implementing an AR display may be secured because the beam directivity angle may be adjusted. In addition, a vertical RGB monolithic LED device may be implemented with the light-emitting device 100 according to one or more embodiments, and because light generated from each of the RGB light-emitting layers (active layers) at different heights in vertical direction of one LED device is mainly extracted through the light concentrator 150, light generated from the RGB light-emitting layers (active layers) at different depths may be collimated with the single micro-lens 160.

In this way, the light-emitting device 100 according to one or more embodiments may include the light concentrator 150, which is a structure capable of concentrating light on the vertically stacked structure 100a, thereby increasing light extraction efficiency and reducing a beam directivity angle of emitting light.

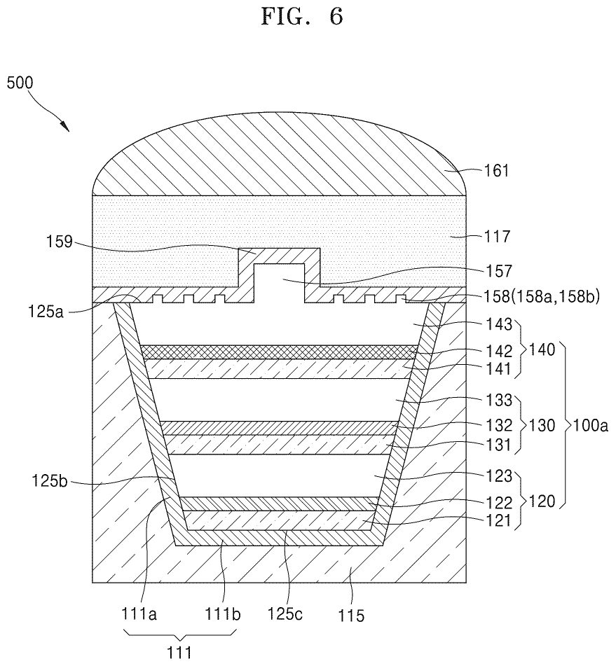

FIGS. 3 to 6 show light-emitting devices 200, 300, 400, and 500 according to various embodiments. FIGS. 3 and 4 show examples in which light-emitting devices 200 and 300 according to embodiments include a plurality of light concentrators 151 and 153 provided to protrude on a vertically stacked structure 100a, and FIGS. 5 and 6 show examples in which light-emitting devices 400 and 500 according to embodiments include light concentrators 155 and 157 formed by patterning a portion of a thickness of an adjacent epi structure of a vertically stacked structure 100a. Components having the same reference numbers in FIGS. 3 to 6 as those of FIGS. 1 and 2 have substantially the same configuration and function as those described with reference to FIGS. 1 and 2, and thus, the descriptions thereof will not be repeated.

As illustrated in FIGS. 3 and 4, the light-emitting devices 200 and 300 according to embodiments may each include a plurality of light concentrators 151 and 153 protrudingly provided on the vertically stacked structure 100a, and at least one of heights and cross-sectional sizes of the plurality of light concentrators 151 and 153 may be the same or different from each other.

FIG. 3 shows an example in which the plurality of light concentrators 151 are formed with the same height and cross-sectional size. FIG. 3 shows three light concentrators 151, but the number of light concentrators 151 is not limited thereto.

FIG. 4 shows an example in which the plurality of light concentrators 153 include three light concentrators 153a, 153b, and 153b formed with different heights and different cross-sectional sizes, but the number of light concentrators 153 is not limited thereto. In addition, FIG. 4 shows an example in which the plurality of light concentrators 153 are formed with different heights and different cross-sectional sizes, but is not limited thereto. At least two of the plurality of light concentrators 153 may have the same height and/or the same cross-sectional size. For example, among the plurality of light concentrators 153 of FIG. 4, a width of the light concentrator 153b located closest to the center of the light-emitting device 300 may be greater than the width of the other light concentrators 153a and 153c, or the height of the light concentrator 153b may be higher than that of the other light concentrators 153a and 153c. However, the width and height relationship of the plurality of light concentrators 153 is not limited thereto.

The plurality of light concentrators 151 and 153 illustrated in FIGS. 3 and 4, as in the light concentrator 150 described with reference to FIGS. 1 and 2, may be formed of a material having a refractive index that is less or greater than that of an adjacent layer of an adjacent epi structure of the third epitaxial structure 140, for example, the second conductive semiconductor layer 143 of the third epitaxial structure 140, but not significantly different from that of the adjacent layer, for example, a similar refractive index, but greater than that of other adjacent layer in a light emission direction, for example, the separation layer 117. Alternatively, the plurality of light concentrators 151 and 153 may be formed of the same material as the uppermost layer of the vertically stacked structure 100a, for example, the second conductive semiconductor layer 143 of the third epi structure 140, as in the light concentrator 150 described with reference to FIGS. 1 and 2. At this time, the plurality of light concentrators 151 and 153 may be formed as a separate layer from the uppermost layer of the vertically stacked structure 100a, but is not limited thereto. For example, the plurality of light concentrators 151 and 153 may also be formed by patterning a portion of a thickness of an adjacent epi structure of the vertically stacked structure 100a, for example, the third epi structure 140. In addition, when the plurality of light concentrators 151 and 153 are formed of the same material as the uppermost layer of the vertically stacked structure 100a, the light-emitting devices 200 and 300 may further include an anti-reflection layer 159 (see FIG. 5).

As illustrated in FIGS. 5 and 6, the light-emitting devices 400 and 500 according to embodiments may each include light concentrators 155 and 157 formed by patterning a portion of a thickness of an adjacent epi structure of the vertically stacked structure 100a, for example, the third epi structure 140.

For example, the light concentrators 155 and 157 may be formed of the same material as the uppermost layer of the vertically stacked structure 100a, for example, the second conductive semiconductor layer 143 of the third epi structure 140, and may be formed by patterning a portion of a thickness of the second conductive semiconductor layer 143.

In order to form the light concentrators 155 and 157 by patterning a portion of the thickness of the second conductive semiconductor layer 143 of the third epi structure 140, the second conductive semiconductor layer 143 may have a thickness greater than a thickness when a light concentrator is formed as a separate layer. After forming the light concentrators 155 and 157 by partially patterning the thickness, a remaining thickness of the second conductive semiconductor layer 143 other than a portion corresponding to the light concentrators 155 and 157 may be the same as or similar to that when forming a light concentrator as a separate layer.

As illustrated in FIG. 6, the light-emitting device 500 according to one or more embodiments may further include a plurality of protrusion patterns 158 formed by patterning a portion of a thickness of an adjacent epi structure of the vertically stacked structure 100a, for example, the third epi structure 140 around the light concentrator 157. The plurality of protrusion patterns 158 may be provided to improve a light extraction efficiency from the vertically stacked structure 100a and to proceed an extracted light to the light concentrator 157. The plurality of protrusion patterns 158 may include, for example, a plurality of annular grating structures 158a formed concentrically around the light concentrator 157. Alternatively, the plurality of protrusion patterns 158 may include a plurality of protrusion patterns 158b arranged two-dimensionally around the light concentrator 157. The light extraction efficiency from the vertically stacked structure 100a may be improved by the plurality of protrusion patterns 158, and amount of light passing through the light concentrator 150 may be increased, and thus, the amount of light condensed by the micro-lens 160 and emitted at a reduced beam directivity angle may be improved.

As shown in FIGS. 5 and 6, when the light concentrators 155 and 157 have the same material as the uppermost layer of the vertically stacked structure 100a, an anti-reflection layer 159 may be further included between the light concentrators 155 and 157 and the separation layer 117 to improve the light extraction efficiency. The anti-reflection layer 159 may be formed overall on a patterned surface of the vertically stacked structure 100a or may cover at least the light concentrators 155 and 157. The anti-reflection layer 159 may be provided to increase the transmittance for each of a plurality of wavelength light, for example, the first to third wavelength light, generated in the vertically stacked structure 100a. The transmittance and reflectance of the anti-reflection layer 159 may be controlled by adjusting a composition material and thickness of the anti-reflection layer 159. The anti-reflection layer 159 may lower the reflectivity and increase the transmittance for the first to third wavelength light by controlling the composition material and thickness. When the light concentrators 155 and 157 have a different material from the uppermost layer of the vertically stacked structure 100a, the anti-reflection layer 159, for example, may have a material having a refractive index that is not significantly different from or similar to the refractive index of the light concentrators 155 and 157. The anti-reflection layer 159 may include, for example, Aluminum Oxide (Al₂O₃), Silicon Nitride (SiN), Titanium Dioxide (TiO₂), Zirconium Dioxide (ZrO₂), Zinc Oxide (ZnO), Tantalum Pentoxide (Ta₂O₃, or Silicon Oxynitride (SiON).

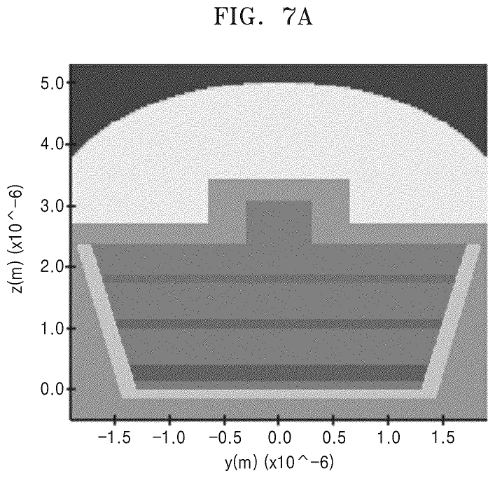

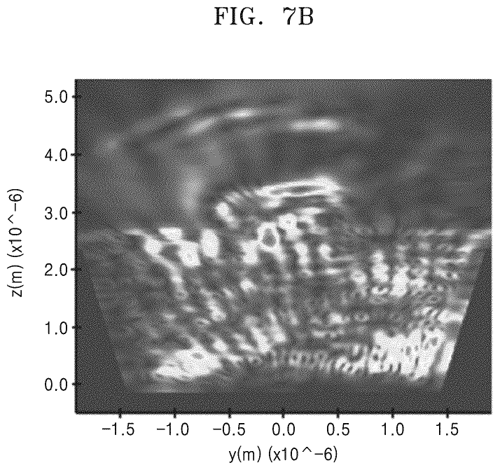

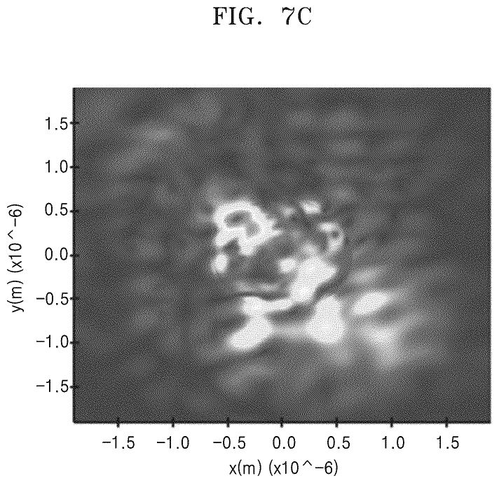

FIG. 7A schematically shows a cross-sectional image of a light-emitting device according to one or more embodiments used in a simulation, FIG. 7B shows a cross-sectional view of a finite-difference time-domain (FDTD) simulation field profile, and FIG. 7C shows a plan view of an FDTD simulation field profile. The light-emitting device of FIG. 7A used in the simulation corresponds to the light-emitting device 400 of FIG. 5. That is, in the light-emitting device 400 according to one or more embodiments, a simulation was performed for a case in which the second conductive semiconductor layer 143 of the third epi-structure 140 (e.g. a blue light-emitting epi-structure) of the vertically stacked structure 100a is an n-GaN layer, and a cylindrical light concentrator 155 having a radius of about 500 nm and a height of about 700 nm is formed in a center of the n-GaN layer. The light concentrator 155 may be manufactured, for example, by a photo process and a dry etching process, and may be composed of n-GaN.

As may be seen from the field profiles of FIGS. 7B and 7C, by providing a light concentrator at a center of an upper surface of a vertically stacked structure, it may be confirmed that light extraction is mainly performed through the light concentrator.

As may be seen from FIGS. 7A to 7C, according to light-emitting devices according to various embodiments, the light concentrator is approximately located at a focus of a micro-lens, and thus, light extracted from the vertically stacked structure substantially corresponds to light that is substantially diverged at a focus position of the micro-lens, and the micro-lens 160 may collimate the incident diverging light. In this way, the emitting light condensed by the micro-lens may have a beam directivity angle reduced by the light concentrator.

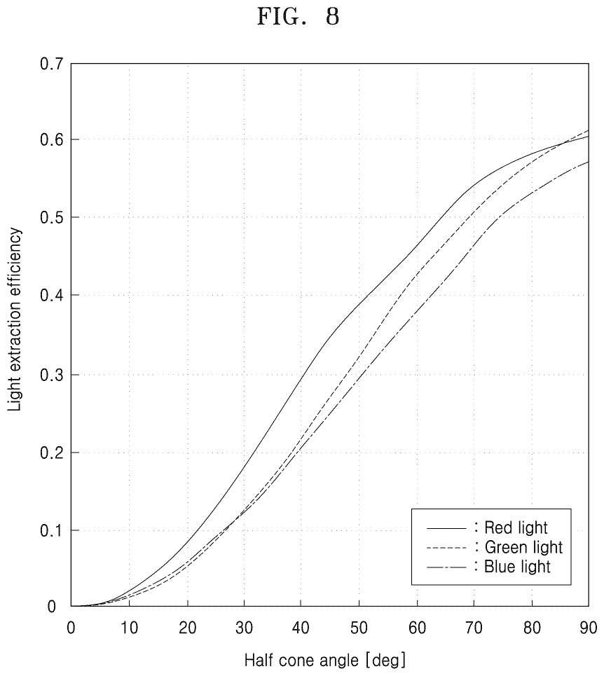

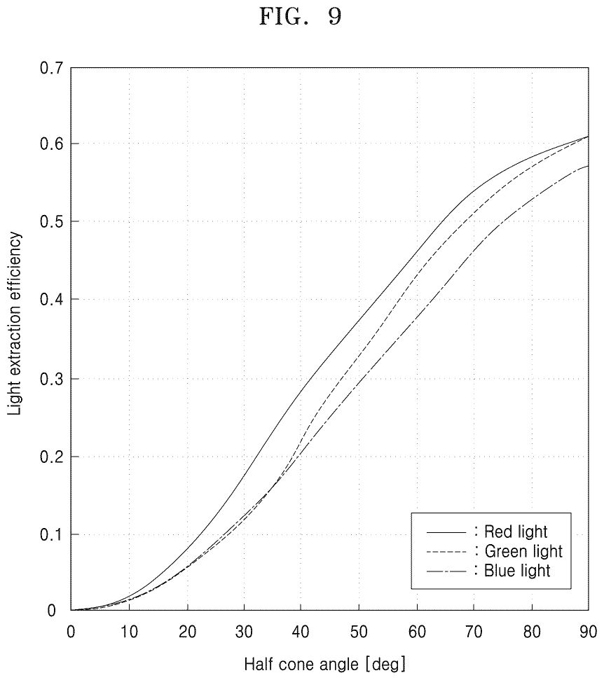

FIGS. 8 and 9 are graphs showing an extraction efficiency of red light, green light, and blue light at different angles of a vertically stacked light-emitting device according to one or more embodiments depending on the parameters of a light concentrator. FIG. 8 shows a light extraction efficiency by angle when a light concentrator of a light-emitting device according to one or more embodiments is formed with a radius r of about 300 nm and a height h of about 300 nm, and FIG. 9 shows a light extraction efficiency by angle when a light concentrator of a light-emitting device according to one or more embodiments is formed with a radius r of about 200 nm and a height h of about 500 nm.

In FIGS. 8 and 9, an x-axis represents a half cone angle degree from the vertical, and an y-axis represents the light extraction efficiency. For example, the graph value at 20 degrees of the x-axis means an efficiency of light being extracted from the light-emitting device into a cone of +−20 degrees from the vertical.

FIG. 10 is a diagram schematically illustrating a display device 1000 according to one or more embodiments. FIG. 10 shows an example of the display device 1000 to which the light-emitting device 100 of FIG. 1 is applied.

Referring to FIG. 10, the display device 1000 includes a backplane substrate 110 and light-emitting devices 100 provided in a two-dimensional array on the backplane substrate 110.

The backplane substrate 110 may include at least one driving element DD. The at least one driving element DD is for electrically driving a plurality of epi structures of a vertically stacked structure, for example, a first epi structure 120, a second epi structure 130, and a third epi structure 140 and may include, for example, a transistor, a thin film transistor, or a high electron mobility transistor (HEMT). However, the driving element DD is not limited thereto, and may further include a capacitor.

The light-emitting device 100 includes a vertically stacked structure 100a including a plurality of epi structures, for example, the first epi structure 120, the second epi structure 130, and the third epi structure 140, which are sequentially stacked in a vertical direction with respect to the backplane substrate 110 and configured to emit different wavelength light each other, a light concentrator 150 provided in a protruding shape with respect to the vertically stacked structure 100a, a micro-lens 160 apart from the light concentrator 150, and a separation layer 117 provided between the light concentrator 150 and the micro-lens 160. The light-emitting device 100 has substantially the same configuration and function as those described with reference to FIGS. 1 and 2, and therefore, the same components are indicated by the same reference numerals as in FIGS. 1 and 2, and the descriptions thereof will not be repeated.

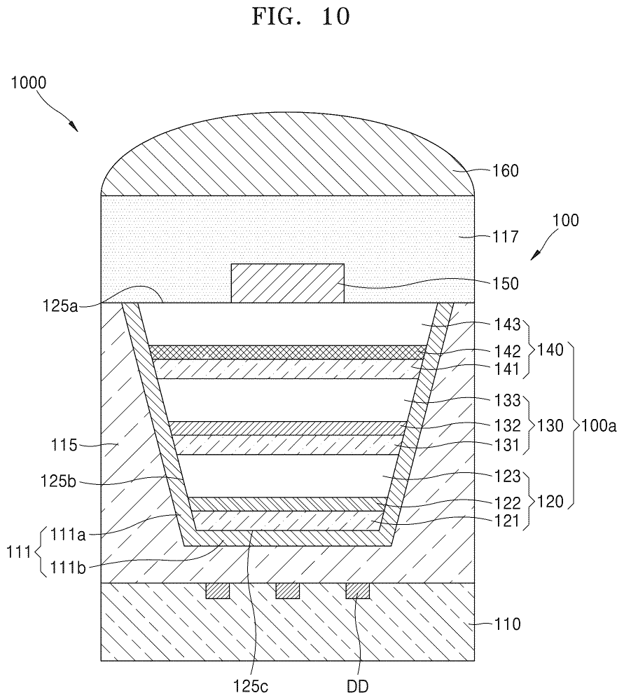

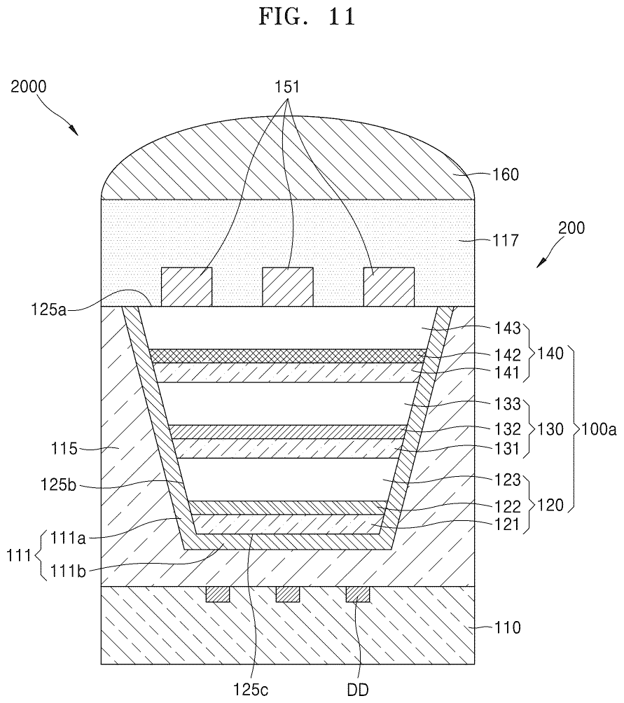

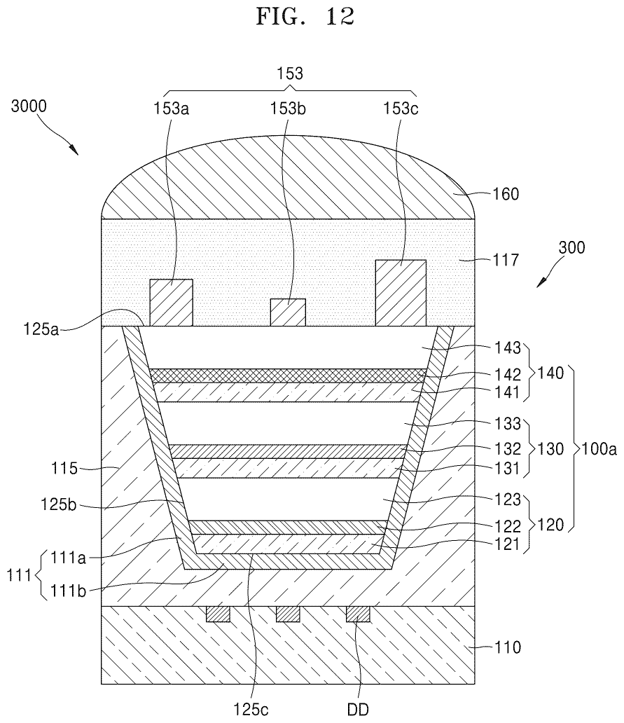

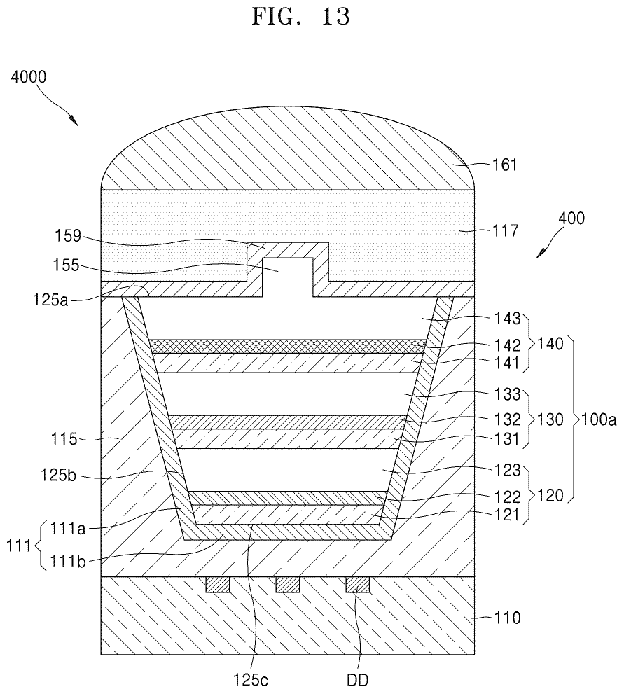

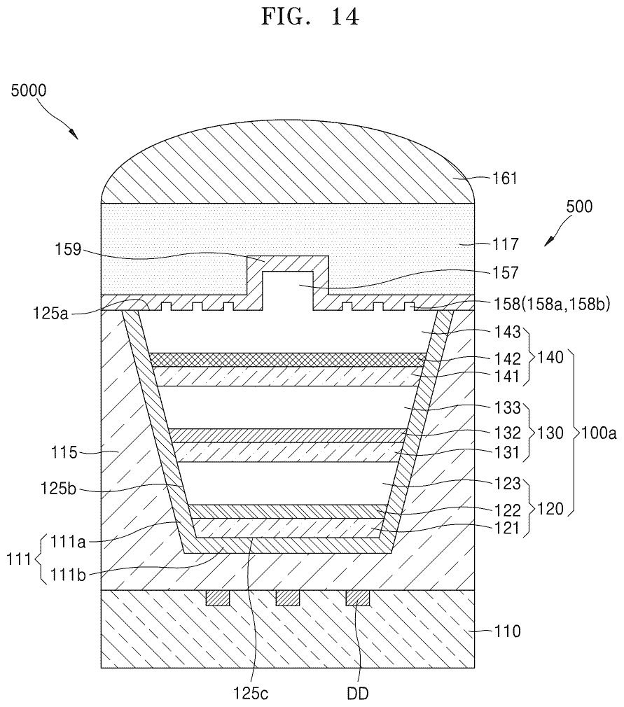

FIGS. 11 to 14 are schematic diagrams of display devices 2000, 3000, 4000, and 5000 according to embodiments, and show the display devices 2000, 3000, 4000, and 5000 to which the light-emitting devices 200, 300, 400, and 500 of FIGS. 3, 4, 5, and 6 are applied, respectively.

Referring to FIGS. 11 to 14, each of the display devices 2000, 3000, 4000, and 5000 includes a backplane substrate 110 and light-emitting devices 200, 300, 400, and 500 provided in a two-dimensional array on the backplane substrate 110. The light-emitting devices 200, 300, 400, and 500 are substantially the same as those described with reference to FIGS. 3 to 6, and therefore, the descriptions thereof will not be repeated.

As described above, each of the display devices 1000, 2000, 3000, 4000, and 5000 according to embodiments has a structure in which each of the light-emitting devices 100, 200, 300, 400, and 500 having a vertically stacked structure according embodiments is combined on the backplane substrate 110, and thus, an area forming one pixel that emits a plurality of wavelength light may be miniaturized. In addition, the display devices 1000, 2000, 3000, 4000, and 5000 may increase the light extraction efficiency from the vertically stacked structure 100a of the light-emitting devices 100, 200, 300, 400, and 500 by the light concentrators 150, 151, 153, 155, and 157, and may also reduce a beam directivity angle of emitting light condensed by the micro-lens 160, and thus, a high-resolution micro-LED display may be implemented. In addition, even though a gap between each micro-LED is narrowed, because the beam directivity angle is adjustable, amount of light required for implementing an AR display may be secured.

The display devices 1000, 2000, 3000, 4000, and 5000 according to embodiments as described above may be applied to various electronic apparatuses.

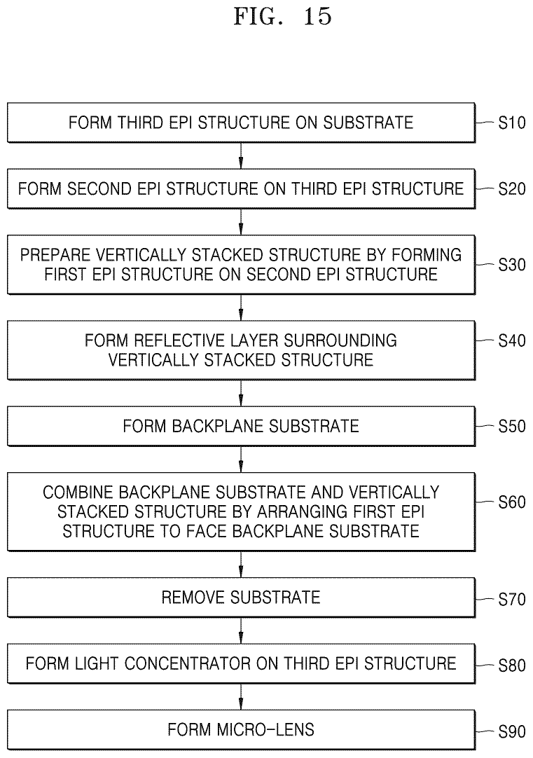

FIG. 15 is for explaining a method of manufacturing a light-emitting device and a display device according to one or more embodiments.

Referring to FIG. 15, the method of manufacturing a light-emitting device and a display device according to one or more embodiments may include step S10 of forming a third epi structure on a substrate, step S20 of forming a second epi structure on the third epi structure, and step S30 of preparing a vertically stacked structure by forming a first epi structure on the second epi structure. The substrate may be a growth substrate for growing an epi structure thereon, and may include, for example, silicon, sapphire, or GaAs. However, it is not limited thereto, and the substrate may include a material other than the materials described above.

Steps S30, S20, and S10 of forming the first epi structure, the second epi structure, and the third epi structure may include a step of forming a first conductive semiconductor layer, a step of forming an active layer, and a step of forming a second conductive semiconductor layer, respectively.

For example, the third epi structure may generate blue light, the second epi structure may generate green light, and the first epi structure may generate red light. Here, the first epi structure, the second epi structure, and the third epi structure are used to match with corresponding components when compared with FIGS. 1 to 6 and FIGS. 10 to 14. When growing the third epi structure, the second epi structure, and the first epi structure on the substrate, the third epi structure formed firstly on the substrate may have relatively more defects than the first epi structure formed later. Therefore, it is desirable that the first epi structure, which generates red light with relatively low light efficiency, is formed last.

After growing a vertically stacked structure of the third epi structure, the second epi structure, and the first epi structure that are sequentially vertically stacked on the substrate, a reflective layer surrounding the vertically stacked structure may be formed (step S40). Alternatively, a passivation layer for protecting the vertically stacked structure may be formed, and the reflective layer may be formed thereafter.

A backplane substrate for implementing a display device may be formed (step S50). The backplane substrate may include at least one driving element. The vertically stacked structure may be flipped over so that the first epi structure is positioned above the backplane substrate and the first epi structure is positioned below the second epi structure and the third epi structure, and the backplane substrate and the vertically stacked structure may be combined (step S60). The vertically stacked structure combined with the backplane substrate may have a structure in which the first epi structure, the second epi structure, and the third epi structure are sequentially stacked in a vertical direction from the backplane substrate. As described above, it is desirable that the first epi structure generating red light is formed last in the growth process, and accordingly, the vertically stacked structure is flipped over and combined with the backplane substrate so that the first epi structure may be located above the backplane substrate.

In this way, the vertically stacked structure is combined with the backplane substrate, and then, the substrate may be removed (step S70). Then, a light concentrator may be formed on the third epi structure (step S80). Then, a micro-lens may be formed to be apart from the light concentrator (step S90). To secure a separation distance between the light concentrator and the micro-lens, a separation layer covering the light concentrator and having a predetermined thickness may be formed, and the micro-lens may be formed on the separation layer.

The method of manufacturing a light-emitting device according to one or more embodiments may follow the process of manufacturing a display device according to one or more embodiments, except for the step of forming the backplane substrate for implementing a display. In order to manufacture the light-emitting device according to one or more embodiments, a support substrate and the vertically stacked structure are combined such that the first epi structure faces a support substrate, and then the substrate may be removed. Afterwards, a light concentrator may be formed on the third epi structure, and a micro-lens may be formed to be apart from the light concentrator.

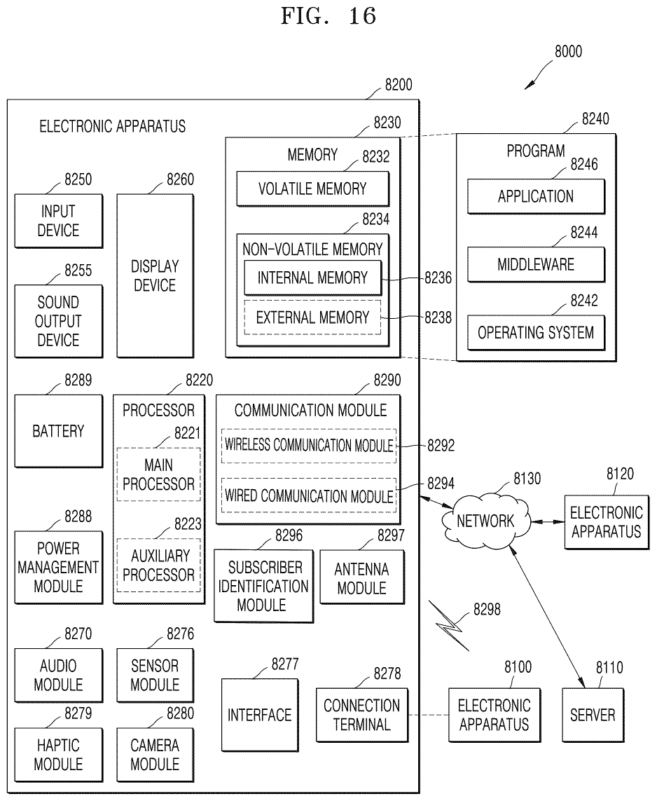

FIG. 16 is a block diagram of an electronic apparatus 8200 including a display device according to one or more embodiments.

Referring to FIG. 16, the electronic apparatus 8200 may be provided within a network environment 8000. In the network environment 8000, the electronic apparatus 8200 may communicate with another electronic apparatus 8100 via a first network 8298 (such as a short-range wireless communication network), or may communicate with another electronic apparatus 8120 and/or a server 8110 via a second network 8130 (such as a long-range wireless communication network). The electronic apparatus 8200 may communicate with the electronic apparatus 8120 through the server 8110. The electronic apparatus 8200 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic apparatus 8200, some of these components may be omitted or other components may be added to the electronic device 8200. Some of these components may be implemented as one integrated circuit. For example, the sensor module 8276 (such as a fingerprint sensor, an iris sensor, or an illuminance sensor, etc.) may be implemented by being embedded in the display device 8260 (such as a display).

The processor 8220 may execute software (such as a program 8240) to control one or more other components (such as hardware, software components, etc.) of an electronic apparatus 8200 connected to the processor 8220 and perform various data processing or calculations. As part of data processing or calculations, the processor 8220 may load commands and/or data received from other components (the sensor module 8210, the communication module 8290, etc.) into a volatile memory 8232, process commands and/or data stored in the volatile memory 8232, and store resulting data in a non-volatile memory 8234. The nonvolatile memory 8234 may include an internal memory 8236 and an external memory 8238. The processor 8220 may include a main processor 8221 (a central processing unit, an application processor, etc.) and an auxiliary processor 8223 (a graphics processing unit, an image signal processor, a sensor hub processor, a communication processor, etc.) that may operate independently or together with the main processor 8221. The auxiliary processor 8223 may use less power than the main processor 8221 and may perform specialized functions.

The auxiliary processor 8223 may control functions and/or states related to some of the components of the electronic apparatus 8200 (such as the display device 8260, the sensor module 8276, and the communication module 8290) on behalf of the main processor 8221 while the main processor 8221 is in an inactive state (sleep state) or together with the main processor 8221 while the main processor 8221 is in an active state (application execution state). The auxiliary processor 8223 (an image signal processor, a communication processor, etc.) may be implemented as a part of other functionally related components (the camera module 8280, the communication module 8290, etc.).

The memory 8230 may store various data required by components of the electronic apparatus 8200 (the processor 8220, the sensor module 8276, etc.). The data may include, for example, software (the program 8240, etc.) and input data and/or output data for commands related thereto. The memory 8230 may include volatile memory 8232 and/or nonvolatile memory 8234.

The program 8240 may be stored as software in the memory 8230 and may include an operating system 8242, middleware 8244, and/or applications 8246.

The input device 8250 may receive commands and/or data to be used in components of the electronic apparatus 8200 (such as the processor 8220) from an outside (such as a user) of the electronic apparatus 8200. The input device 8250 may include a remote controller, a microphone, a mouse, a keyboard, and/or a digital pen (such as a stylus pen).

The audio output device 8255 may output an audio signal to an outside of the electronic apparatus 8200. The audio output device 8255 may include a speaker and/or a receiver. The speaker may be used for general purposes such as multimedia playback or recording playback, and the receiver may be used to receive incoming calls. The receiver may be incorporated as part of the speaker or may be implemented as an independent separate device.

The display device 8260 may visually provide information to an outside of the electronic apparatus 8200. The display device 8260 may include a display, a holographic device, or a projector and a control circuit for controlling a corresponding device. The display device 8260 may include a display device according to one or more embodiments. The display device 8260 may include touch circuitry configured to sense a touch, and/or sensor circuitry (such as a pressure sensor) configured to measure the intensity of a force generated by a touch.

The audio module 8270 may convert sound into an electrical signal, or vice versa, convert an electrical signal into sound. The audio module 8270 may acquire sound through the input device 8250, or output sound through a speaker and/or headphones of the audio output device 8255, and/or another electronic apparatus (such as the electronic apparatus 8100) directly or wirelessly connected to the electronic apparatus 8200.

The sensor module 8276 may sense an operating status (power, temperature, etc.) of the electronic apparatus 8200 or an external environmental status (such as the user status) and generate an electric signal and/or data value corresponding to a sensed status. The sensor module 8276 may include a gesture sensor, a gyro sensor, a barometric pressure sensor, a magnetic sensor, an acceleration sensor, a grip sensor, a proximity sensor, a color sensor, an Infrared (IR) sensor, a biometric sensor, a temperature sensor, a humidity sensor, and/or an illuminance sensor.

The interface 8277 may support one or more designated protocols that may be used to allow the electronic apparatus 8200 to connect directly or wirelessly with another electronic device (such as the electronic apparatus 8100). The interface 8277 may include a high definition multimedia interface (HDMI), a universal serial bus (USB) interface, an SD card interface, and/or an audio interface.

A connection terminal 8278 may include a connector through which the electronic apparatus 8200 may be physically connected to another electronic apparatus (e.g., the electronic apparatus 8100). The connection terminal 8278 may include an HDMI connector, a USB connector, an SD card connector, and/or an audio connector (e.g., a headphone connector).

The haptic module 8279 may convert an electrical signal into a mechanical stimulus (vibration, movement, etc.) or an electrical stimulus that the user may perceive through tactile or kinesthetic sense. The haptic module 8279 may include a motor, a piezoelectric element, and/or an electrical stimulation device.

The camera module 8280 may capture still images and moving images. The camera module 8280 may include a lens assembly including one or more lenses, image sensors, image signal processors, and/or flashes. The lens assembly included in the camera module 8280 may collect light emitted from a subject, which is an imaging target.

The power management module 8288 may manage power supplied to the electronic apparatus 8200. The power management module 8288 may be implemented as part of a Power Management Integrated Circuit (PMIC).

The battery 8289 may supply power to components of the electronic apparatus 8200. The battery 8289 may include a non-rechargeable primary cell, a rechargeable secondary cell, and/or a fuel cell.

The communication module 8290 may establish a direct (wired) communication channel and/or wireless communication channel between the electronic apparatus 8200 and other electronic apparatuses (the electronic apparatus 8100, an electronic apparatus 8120, server 8110, etc.) and may support a performance of communication through the established communication channels. The communication module 8290 may include one or more communication processors that operate independently of the processor 8220 (e.g., an application processor) and support direct communication and/or wireless communication. The communication module 8290 may include a wireless communication module 8292 (a cellular communication module, a short-range wireless communication module, a Global Navigation Satellite System (GNSS) communication module, etc.) and/or a wired communication module 8294 (a Local Area Network (LAN) communication module, or a power line communication module, etc.). Among these communication modules, a corresponding communication module may communicate with other electronic apparatuses through the first network 8298 (a short-range communication network, such as Bluetooth, WiFi Direct, or Infrared Data Association (IrDA)) or the second network 8130 (a telecommunication network, such as a cellular network, the Internet, or a computer network (LAN, WAN, etc.)). The various types of communication modules may be integrated into one component (a single chip, etc.) or implemented as a plurality of components (plural chips) separate from each other. The wireless communication module 8292 may identify and authenticate the electronic apparatus 8200 within a communication network, such as the first network 8298 and/or the second network 8130 by using subscriber information (such as, International Mobile Subscriber Identifier (IMSI)) stored in a subscriber identification module 8296.

The antenna module 8297 may transmit or receive signals and/or power to and from an outside (such as other electronic apparatuses). An antenna may include a radiator having a conductive pattern formed on a substrate (such as a PCB). The antenna module 8297 may include one or a plurality of antennas. When the plurality of antennas are included in the antenna module 8297, an antenna suitable for a communication manner used in a communication network, such as the first network 8298 and/or the second network 8130 from among the plurality of antennas may be selected by the communication module 8290. Signals and/or power may be transmitted or received between the communication module 8290 and the other electronic apparatus through the selected antenna. In addition to the antenna, other components (such as an RFIC, etc.) may be included as a part of the antenna module 8297.

Some of the components are connected to each other through a communication manner between peripheral devices (a bus, a General Purpose Input and Output (GPIO), a Serial Peripheral Interface (SPI), a Mobile Industry Processor Interface (MIPI), etc.), and may interchange signals (commands, data, etc.).

The command or data may be transmitted or received between the electronic apparatus 8200 and the external electronic apparatus 8120 through the server 8110 connected to the second network 8130. The other electronic apparatuses 8100 and 8120 may be the same or different types of the electronic apparatus 8200. All or some of operations performed in the electronic apparatus 8200 may be performed in one or more of the other electronic apparatuses 8100 and 8120 and the server 8110. For example, when the electronic apparatus 8200 needs to perform a function or service, the electronic apparatus 8200 may request one or more other electronic apparatuses to perform part or all function or service instead of executing the function or service itself. One or more other electronic apparatuses receiving the request may execute an additional function or service related to the request, and transmit a result of the execution to the electronic apparatus 8200. For this purpose, cloud computing, distributed computing, and/or client-server computing technologies may be used.

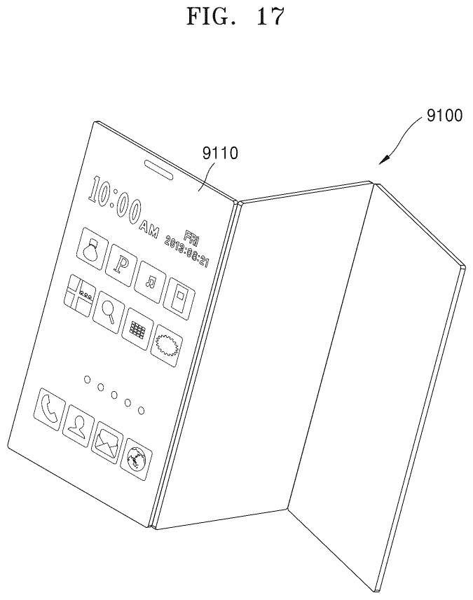

FIG. 17 illustrates an example in which an electronic apparatus according to one or more embodiments is applied to a mobile device 9100. The mobile device 9100 may include a display device 9110, and the display device 9110 may include display devices according to one or more embodiments. The display device 9110 may have a foldable structure, for example, a multi-foldable structure.

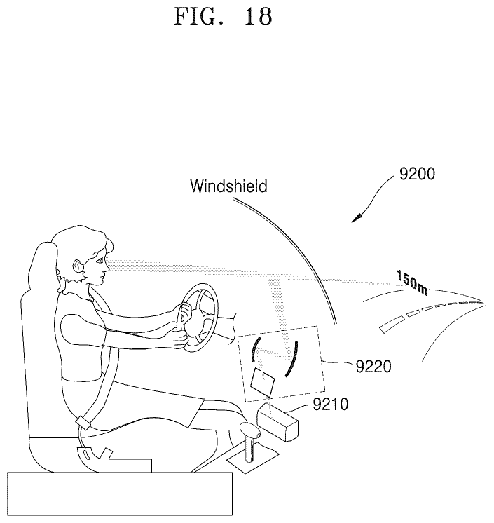

FIG. 18 illustrates an example in which a display device according to one or more embodiments is applied to a vehicle. The display device may be a head-up display device 9200 for a vehicle and may include a display 9210 provided in an area of the vehicle and an optical path change member 9220 that changes the optical path so that a driver may view an image generated by the display 9210.

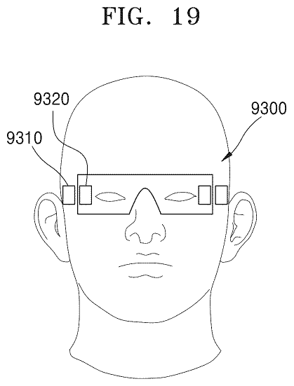

FIG. 19 illustrates an example in which a display device according to one or more embodiments is applied to augmented reality glasses 9300 or virtual reality glasses. The augmented reality glasses 9300 may include projection systems 9310 that forms an image and waveguides 9320 that guides the image from the projection systems 9310 to enter user's eyes. Each projection system 9310 may include the display device according to one or more embodiments. Each waveguide 9320 may be provided, for example, in a glasses frame.

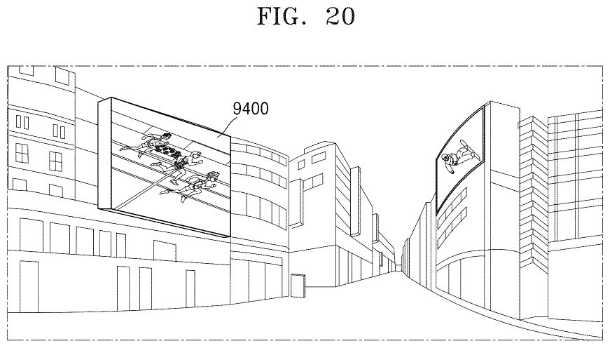

FIG. 20 illustrates an example in which a display device according to one or more embodiments is applied to a large signage 9400. The signage 9400 may be used for outdoor advertising using a digital information display, and may control advertising content, etc. through a communication network. The signage 9400 may be implemented, for example, through an electronic apparatus described with reference to FIG. 16.

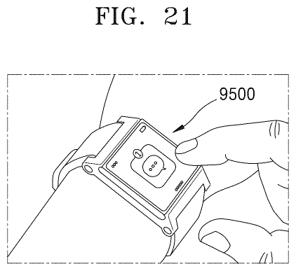

FIG. 21 illustrates an example in which a display device according to one or more embodiments is applied to a wearable display 9500. The wearable display 9500 may include a display device according to one or more embodiments and may be implemented through an electronic apparatus described with reference to FIG. 16.

The display device according to one or more embodiments may also be applied to various products such as a rollable TV and a stretchable display.

While the light-emitting device, the display device, the method of manufacturing thereof, and the electronic apparatus including the same have been described with reference to the embodiments illustrated in the drawings, it will be understood by those of ordinary skill in the art that various changes in form and details may be made therein without departing from the spirit and scope of the inventive concept.

In addition, the present disclosure may have the following configuration.

According to an aspect of the disclosure, a light-emitting device may include: a vertically stacked structure including a plurality of epi structures that are sequentially stacked in a vertical direction and provided to generate different wavelength light from each other; a light concentrator provided in a protruding shape with respect to the vertically stacked structure; a micro-lens apart from the light concentrator; and a separation layer provided between the light concentrator and the micro-lens, wherein each of the plurality of epi structures includes a first conductive semiconductor layer, an active layer, and a second conductive semiconductor layer, and the light concentrator is provided to reduce a beam directivity angle of an emitting light condensed by the micro-lens.

The light-emitting device further includes a reflective layer formed to surround at least one of side and bottom surfaces of the vertically stacked structure.

The light concentrator is formed to protrude from a center of an upper surface of the vertically stacked structure.

The light concentrator is formed in a shape of any one of a columnar shape, a cone shape, a pyramid shape, a truncated cone shape, and a truncated pyramid shape to protrude from the vertically stacked structure, and

a cross-sectional shape of the light concentrator is any one of a circle, an ellipse, a square, and a polygon.

The light concentrator is formed to have a size of about 50% or less of a size of an upper surface of the vertically stacked structure or a width of the upper surface and a height equal to or less than 1 μm.

The light concentrator has a refractive index greater than that of the separation layer.

In the light-emitting device, an adjacent epi structure of the vertically stacked structure is based on a Group III-V compound semiconductor, and
the light concentrator includes either TiO₂ or SiN.

The light concentrator is formed by patterning a portion of a thickness of an adjacent epi structure of the vertically stacked structure, and
an anti-reflection layer is further included between the light concentrator and the separation layer.

The light-emitting device further includes a plurality of protrusion patterns formed by patterning the adjacent epi structure of the vertically stacked structure around the light concentrator,
wherein the plurality of protrusion patterns includes a plurality of annular grating structures formed around the light concentrator or a plurality of protrusion patterns two-dimensionally arranged around the light concentrator.

The light concentrator includes a plurality of light concentrators provided to protrude on the vertically stacked structure.

The plurality of light concentrators are provided to have at least one of heights and cross-sectional sizes equal to or different from each other.

The vertically stacked structure is formed to have an inclined side surface facing the light concentrator.

According to an aspect of the disclosure, a display device may include a backplane substrate including at least one driving element and light-emitting devices provided in a two-dimensional array on the backplane substrate.

The light-emitting device may include: a vertically stacked structure including a plurality of epi structures that are sequentially stacked in a vertical direction with respect to the backplane substrate and provided to generate different wavelength light from each other; a light concentrator provided in a protruding shape with respect to the vertically stacked structure; a micro-lens apart from the light concentrator; and a separation layer provided between the light concentrator and the micro-lens, wherein each of the plurality of epi structures includes a first conductive semiconductor layer, an active layer, and a second conductive semiconductor layer, and the light concentrator is provided to reduce a beam directivity angle of emitting light condensed by the micro-lens.

The display device further includes a reflective layer formed to surround at least one of side and bottom surfaces of the vertically stacked structure.

The light concentrator is formed to protrude from a center of an upper surface of the vertically stacked structure.

The light concentrator is formed in a shape of any one of a columnar shape, a cone shape, a pyramid shape, a truncated cone shape, and a truncated pyramid shape to protrude from the vertically stacked structure, and
a cross-sectional shape of the light concentrator is any one of a circle, an ellipse, a square, and a polygon.

The light concentrator is formed to a size of about 50% or less of a size of an upper surface of the vertically stacked structure or a width of the upper surface and a height equal to or less than 1 μm.

The light concentrator has a refractive index greater than that of the separation layer.

In the display device, an adjacent epi structure of the vertically stacked structure is based on a Group III-V compound semiconductor, and the light concentrator includes either TiO₂ or SiN.

The light concentrator is formed by patterning a portion of a thickness of an adjacent epi structure of the vertically stacked structure, and an anti-reflection layer is further included between the light concentrator and the separation layer.

The display device further includes a plurality of protrusion patterns formed by patterning an adjacent epi structure of the vertically stacked structure around the light concentrator. The plurality of protrusion patterns include a plurality of annular grating structures formed around the light concentrator or a plurality of protrusion patterns two-dimensionally arranged around the light concentrator.

The light concentrator includes a plurality of light concentrators provided to protrude on the vertically stacked structure.

The plurality of light concentrators are provided to have at least one of heights and cross-sectional sizes equal to or different from each other.

The vertically stacked structure is formed to have an inclined side surface facing the light concentrator.

According to an aspect of the disclosure, a method of manufacturing a display device, may include: forming a vertically stacked structure including a plurality of epi structures that are vertically stacked on a substrate and provided to generate different wavelength light from each other; forming a backplane substrate; combining the backplane substrate and the vertically stacked structure so that the vertically stacked structure faces the backplane substrate; removing the substrate; forming a light concentrator in a protruding shape with respect to the vertically stacked structure; forming a separation layer on the light concentrator; and forming a micro-lens on the separation layer.

The forming of each of the plurality of epi structures includes forming a first conductive semiconductor layer, forming an active layer, and forming a second conductive semiconductor layer.

The light concentrator is provided to reduce a beam directivity angle of emitting light condensed by the micro-lens.

According to an aspect of the disclosure, an electronic apparatus may include a display device including a backplane substrate including at least one driving element, and light-emitting devices provided in a two-dimensional array on the backplane substrate. The light-emitting device may include: a vertically stacked structure including a plurality of epi structures that are sequentially stacked in a vertical direction with respect to the backplane substrate and provided to generate different wavelength light from each other; a light concentrator provided in a protruding shape with respect to the vertically stacked structure; a micro-lens apart from the light concentrator; and a separation layer provided between the light concentrator and the micro-lens. Each of the plurality of epi structures includes a first conductive semiconductor layer, an active layer, and a second conductive semiconductor layer. The light concentrator is provided to reduce a beam directivity angle of emitting light condensed by the micro-lens.

A light-emitting device having a vertically stacked structure of epi structures according to one or more embodiments and a display device including the same includes a light concentrator, and thus may increase light extraction efficiency from the vertically stacked structure and reduce a beam directivity angle of emitting light condensed by the micro-lens.

A high-resolution micro-LED display may be implemented by applying the light-emitting device according to one or more embodiments to the micro-LED, and even when a gap between each of the micro-LEDs is narrowed and the size of the micro-lens is limited due to the reduced gap, the beam directivity angle may be adjusted, and the amount of light required for implementing an AR display may be secured.

A display device including one or more embodiments may be applied to various electronic apparatuses.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device comprising:
a vertically stacked structure including a plurality of epitaxial structures stacked in a vertical direction and provided to generate different wavelength lights, respectively;
a light concentrator provided in a protruding shape with respect to the vertically stacked structure;
a micro-lens apart from the light concentrator; and
a separation layer between the light concentrator and the micro-lens,
wherein each of the plurality of epitaxial structures comprises a first conductive semiconductor layer, an active layer, and a second conductive semiconductor layer, and
the light concentrator is configured to reduce a beam directivity angle of emitting light condensed by the micro-lens.

2. The light-emitting device of claim 1, further comprising a reflective layer that surround at least one of side and bottom surfaces of the vertically stacked structure.

3. The light-emitting device of claim 1, wherein the light concentrator protrudes from a center of an upper surface of the vertically stacked structure.

4. The light-emitting device of claim 1, wherein the light concentrator has a shape of any one of a columnar shape, a cone shape, a pyramid shape, a truncated cone shape, and a truncated pyramid shape to protrude from the vertically stacked structure, and
a cross-sectional shape of the light concentrator is any one of a circle, an ellipse, a square, and a polygon.

5. The light-emitting device of claim 1, wherein a width of the light concentrator is 50% or less of a width of an upper surface of the vertically stacked structure, or a height of the light concentrator is less than or equal to 1 μm.

6. The light-emitting device of claim 1, wherein a refractive index of the light concentrator is greater than a refractive index of the separation layer.

7. The light-emitting device of claim 1, wherein an epitaxial structure adjacent to the light concentrator of the vertically stacked structure is based on a Group III-V compound semiconductor, and
the light concentrator comprises either titanium dioxide (TiO₂) or silicon nitride (SiN).

8. The light-emitting device of claim 1, wherein the light concentrator is formed by patterning a portion of a thickness of an epitaxial structure adjacent to the light concentrator of the vertically stacked structure, and
further comprising an anti-reflection layer between the light concentrator and the separation layer.

9. The light-emitting device of claim 1, further comprising a plurality of protrusion patterns formed by patterning an epitaxial structure adjacent to the light concentrator of the vertically stacked structure around the light concentrator,
wherein the plurality of protrusion patterns comprises a plurality of annular grating structures around the light concentrator, or the plurality of protrusion patterns are two-dimensionally arranged around the light concentrator.

10. The light-emitting device of claim 1, wherein the light concentrator comprises a plurality of light concentrators that protrude from the vertically stacked structure,
wherein the plurality of light concentrators have the same or different heights or the same or different cross sectional sizes.

11. A display device comprising:
a backplane substrate comprising at least one driving element and light-emitting devices provided in a two-dimensional array on the backplane substrate,
wherein at least one of the light-emitting devices comprises:
a vertically stacked structure comprising a plurality of epitaxial structures stacked in a vertical direction with respect to the backplane substrate and configured to generate different wavelength lights from each other;
a light concentrator provided in a protruding shape with respect to the vertically stacked structure;
a micro-lens apart from the light concentrator; and
a separation layer between the light concentrator and the micro-lens,
wherein each of the plurality of epitaxial structures comprises a first conductive semiconductor layer, an active layer, and a second conductive semiconductor layer, and
the light concentrator is configured to reduce a beam directivity angle of emitting light condensed by the micro-lens.

12. The display device of claim 11, further comprising a reflective layer that surrounds at least one of side and bottom surfaces of the vertically stacked structure.

13. The display device of claim 11, wherein the light concentrator protrudes from a center of an upper surface of the vertically stacked structure.

14. The display device of claim 11, wherein the light concentrator has a shape of any one of a columnar shape, a cone shape, a pyramid shape, a truncated cone shape, and a truncated pyramid shape to protrude from the vertically stacked structure, and
a cross-sectional shape of the light concentrator is any one of a circle, an ellipse, a square, and a polygon.

15. The display device of claim 11, wherein a width of the light concentrator is 50% or less of a width of an upper surface of the vertically stacked structure and a height of the light concentrator is equal to or less than 1 μm.

16. The display device of claim 11, wherein a refractive index of the light concentrator is greater than that of the separation layer.

17. The display device of claim 11, wherein an epitaxial structure adjacent to the light concentrator of the vertically stacked structure is based on a Group III-V compound semiconductor, and
the light concentrator comprises either titanium dioxide (TiO₂) or silicon nitride (SiN).

18. The display device of claim 11, wherein the light concentrator is formed by patterning a portion of a thickness of an epitaxial structure adjacent to the light concentrator of the vertically stacked structure, and
further comprising an anti-reflection layer between the light concentrator and the separation layer.

19. The display device of claim 11, wherein the light concentrator comprises a plurality of light concentrators that protrude on the vertically stacked structure, and
the plurality of light concentrators have the same or different heights or the same or different cross-sectional sizes.

20. A method of manufacturing a display device, the method comprising:
forming a vertically stacked structure including a plurality of epitaxial structures vertically stacked on a substrate and configured to generate different wavelength lights from each other;
forming a backplane substrate;
combining the backplane substrate and the vertically stacked structure so that the vertically stacked structure faces the backplane substrate;
removing the substrate;
forming a light concentrator in a protruding shape with respect to the vertically stacked structure;
forming a separation layer on the light concentrator; and
forming a micro-lens on the separation layer,
wherein the forming of each of the plurality of epitaxial structures comprises forming a first conductive semiconductor layer, forming an active layer, and forming a second conductive semiconductor layer, and
the light concentrator is configured to reduce a beam directivity angle of emitting light condensed by the micro-lens.
